(19) United States
(12) Patent Application Publication
(10) Pub. No.: US 2025/0012841 A1
(43) Pub. Date: Jan. 9, 2025

(54) ULTRA-HIGH FREQUENCY PARTIAL DISCHARGE DETECTION SENSOR HAVING LEAK-TIGHT STRUCTURE

(71) Applicant: SUNGLIM HEAVY ELECTRIC CO., LTD., Busan (KR)

(72) Inventor: Kyu Ho LEE, Busan (KR)

(73) Assignee: SUNGLIM HEAVY ELECTRIC CO., LTD., Busan (KR)

(21) Appl. No.: 18/893,911

(22) Filed: Sep. 23, 2024

Related U.S. Application Data
(63) Continuation of application No. PCT/KR2024/008371, filed on Jun. 18, 2024.

(30) Foreign Application Priority Data
Jun. 28, 2023 (KR) 10-2023-0083766

(51) Int. Cl. G01R 31/12; G01R 31/327

(52) U.S. Cl. CPC G01R 31/1254; G01R 31/3275

(57) ABSTRACT

An ultra-high frequency (UHF) partial discharge detection sensor having a leak-tight structure, includes a flange portion having a through hole formed therein, an electrode rod inserted through the through hole formed in the flange portion, a sensor unit provided at an upper end of the electrode rod to detect partial discharge ultra-high frequency, a sealing member provided between the electrode rod and the flange portion, and a cover member supporting a lower end of the sealing member.

### CROSS REFERENCE TO RELATED APPLICATION

This application is a Continuation of PCT International Patent Application No. PCT/KR2024/008371 filed on Jun. 18, 2024, which claims priority to Korean Patent Application No. 10-2023-0083766 filed on Jun. 28, 2023 which are all hereby incorporated by reference in their entirety.

### BACKGROUND

The present disclosure is for detecting partial discharge occurring inside a gas-insulated switchgear, and more specifically, for a sensor for detecting partial discharge of a gas-insulated switchgear.

Partial discharge (PD) refers to a discharge phenomenon that occurs locally around or inside an insulator under high voltage stress. In addition to causing continuous power loss due to power leakage, when the affect accumulates, it can cause irreversible physical or chemical changes to an insulating material, which may completely stop the power supply to the device where the partial discharge occurred, or in severe cases, cause the device to explode.

Therefore, in order to operate the device normally, it is important to detect the partial discharge discussed above and prevent accidents in advance. In the case of the gas-insulated switchgear, conventionally, an external sensor for detecting partial discharge is attached to the external surface of the device to detect whether there is a partial discharge.

In such cases, due to the nature of power equipment, there is a problem that the sensor malfunctions or the reliability of the measurement results decreases due to entering of the noise generated from such equipment or devices being mixed in because of the equipment or devices that generate strong electromagnetic waves in the vicinity.

In order to improve this problem, Korean Registration Publication No. 10-0858270, which is the related prior art, discloses a switch diagnostic device that can diagnose the cause of a defect without dismantling the operating power equipment, and in particular, can diagnose external noise and defects, and Korean Patent Publication No. 10-0893396 discloses a partial discharge detection device that detects partial discharge occurring during the operation of a gas insulation device using a built-in sensor.

However, in the case of the prior art, there is a risk of leakage of insulating gas due to damage to the welding area, or the like when an impact occurs.

Therefore, research is needed on an ultra-high frequency (UHF) partial discharge detection sensor having a leak-tight structure that can prevent leakage of insulating gas without damage or deformation even when a strong impact is applied to the partial discharge detection sensor and the assembly.

### SUMMARY

Unlike the conventional structure in which a ceramic portion is welded to a flange portion, an object of the present disclosure is to provide a UHF partial discharge detection sensor having a leak-tight structure in which a protrusion portion corresponding to a ceramic portion is formed on a flange portion, thereby preventing damage or deformation of a welding portion when an impact occurs and maintaining internal sealing, thereby effectively preventing leakage of insulating gas.

The problems to be solved by the present disclosure are not limited to the problems mentioned above, and other problems to be solved by the present disclosure that are not mentioned herein can be clearly understood by those skilled in the art to which the present disclosure belongs from the description below.

According to one embodiment of the present disclosure, there is provided an ultra-high frequency (UHF) partial discharge detection sensor having a leak-tight structure, the UHF partial discharge detection sensor including: a flange portion having a through hole formed therein; an electrode rod inserted through the through hole formed in the flange portion; a sensor unit provided at an upper end of the electrode rod to detect partial discharge ultra-high frequency; a sealing member provided between the electrode rod and the flange portion; and a cover member supporting a lower end of the sealing member.

Moreover, the flange portion may be integrally formed to include a bottom portion formed in a circular plate shape having a first diameter and a protrusion portion formed in a columnar shape having a second diameter by protruding from a center of the bottom portion, the through hole may be formed by penetrating the centers of the bottom portion and the protrusion portion, and the first diameter may be larger than the second diameter.

The sealing member may include a first O-ring coupled to a surface of the bottom portion of the flange portion, and a second O-ring coupled to an inner circumference of the protrusion portion of the flange portion.

A seating groove may be formed on one surface of the cover member, and a seating member may be inserted into the seating groove to support the lower end of the sealing member.

Moreover, the seal member may include a fastening protrusion having a preset pattern formed on one side of a lower end surface in contact with the sealing member, the seating member may include a fastening groove formed to correspond to the fastening protrusion on one side of a surface in contact with the lower end surface of the sealing member, and a first filler may be applied to a joint surface of the seating member and the sealing member to fill a portion between the fixing member and the sealing member with an air gap.

According to the present disclosure, by including the flange portion in which the protrusion portion is formed, when an impact occurs, damage or deformation of a welded portion can be prevented, and internal sealing can be maintained, thereby effectively preventing leakage of insulating gas.

### BRIEF DESCRIPTION OF THE DRAWINGS

FIG. 1 is a configuration diagram of an ultra-high frequency (UHF) partial discharge detection sensor having a leak-tight structure according to one embodiment of the present disclosure.

FIG. 2 and FIG. 3 are views for explaining a flange portion of the UHF partial discharge detection sensor having a leak-tight structure according to one embodiment of the present disclosure.

FIG. 4 is a view for explaining a sealing member of the UHF partial discharge detection sensor having a leak-tight structure according to one embodiment of the present disclosure.

FIG. 5 is a view for explaining a cover member of the UHF partial discharge detection sensor having a leak-tight structure according to one embodiment of the present disclosure.

FIG. 6 is a perspective view of the cover member and the sealing member of the UHF partial discharge detection sensor having a leak-tight structure according to one embodiment of the present disclosure.

FIG. 7 and FIG. 8 are views for explaining coupling of the cover member and the sealing member of the UHF partial discharge detection sensor having a leak-tight structure according to one embodiment of the present disclosure.

FIG. 9 to FIG. 12 are views for explaining a prior art of the UHF partial discharge detection sensor having a leak-tight structure according to one embodiment of the present disclosure.

### DETAILED DESCRIPTION

Specific details including the problem to be solved, the means for solving the problem, and the effect of the invention for the present disclosure as described above are included in embodiments and drawings described below. The advantages and features of the present disclosure, and the method for achieving them, will be clarified by referring to the embodiments described below in detail together with the attached drawings.

The scope of the rights of the present disclosure is not limited to the embodiments described below, and may be variously modified and implemented by a person with common knowledge in the relevant technical field within a scope that does not deviate from the technical essence of the present disclosure.

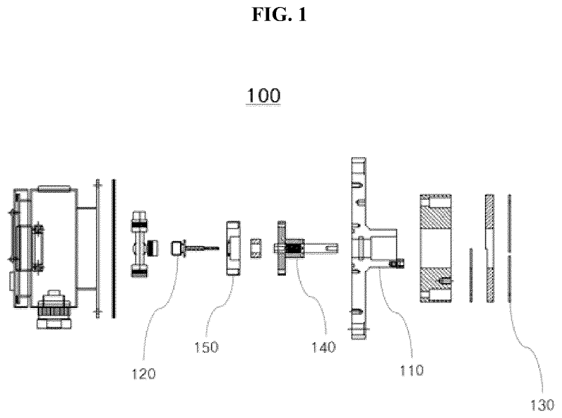

The title of the invention, which is the present disclosure, is explained in detail with reference to the attached FIG. 1.

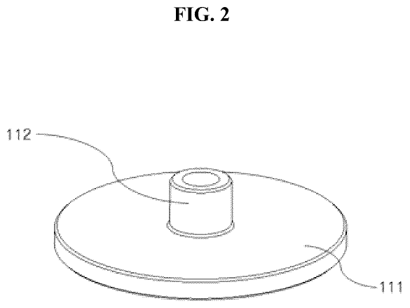

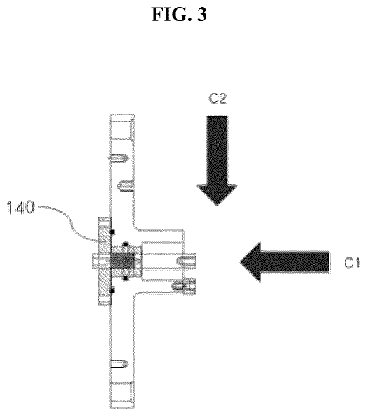

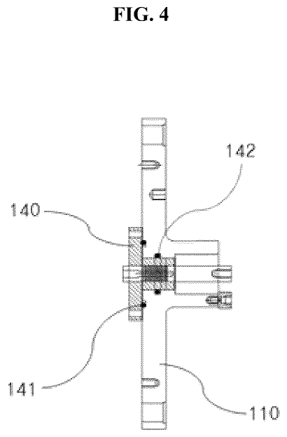

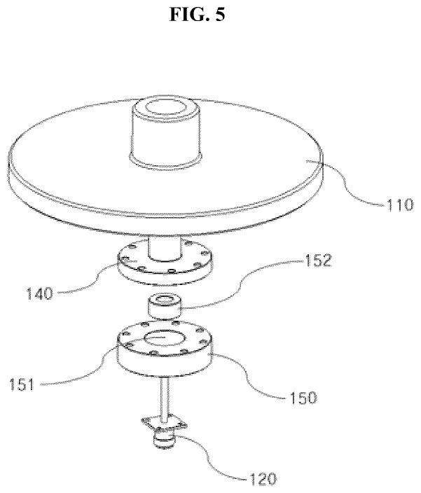

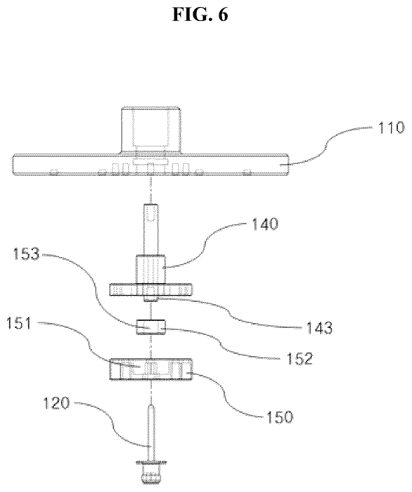

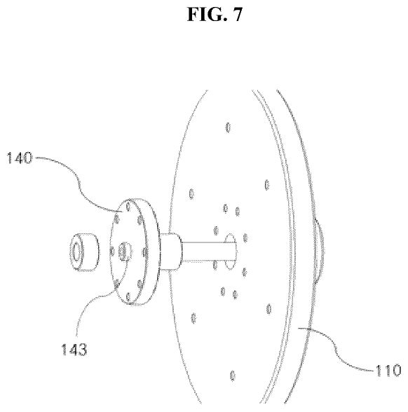

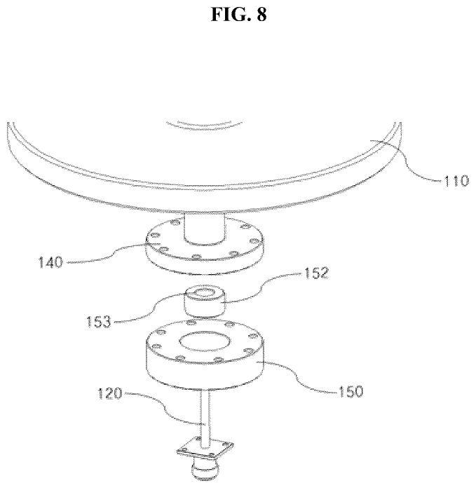

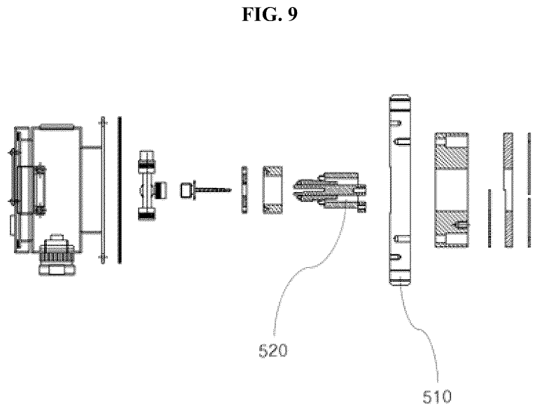

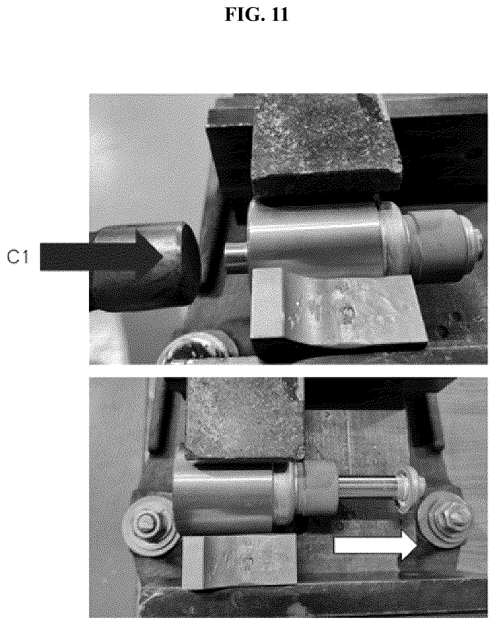

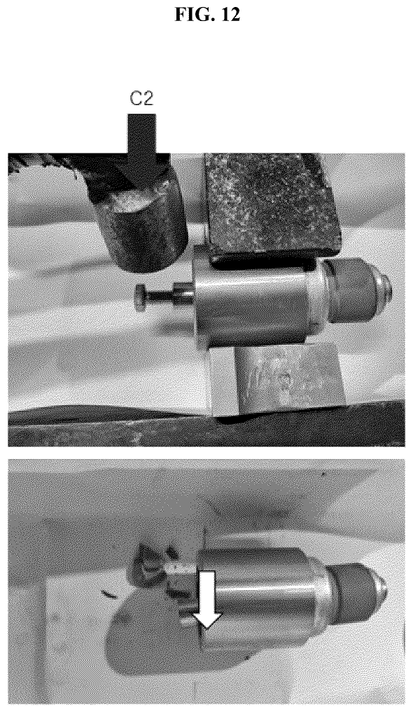

FIG. 1 is a configuration diagram of an ultra-high frequency (UHF) partial discharge detection sensor having a leak-tight structure according to one embodiment of the present disclosure, FIG. 2 and FIG. 3 are views for explaining a flange portion of the UHF partial discharge detection sensor having a leak-tight structure according to one embodiment of the present disclosure, FIG. 4 is a view for explaining a sealing member of the UHF partial discharge detection sensor having a leak-tight structure according to one embodiment of the present disclosure, FIG. 5 is a view for explaining a cover member of the UHF partial discharge detection sensor having a leak-tight structure according to one embodiment of the present disclosure, FIG. 6 is a perspective view of the cover member and the sealing member of the UHF partial discharge detection sensor having a leak-tight structure according to one embodiment of the present disclosure, FIG. 7 and FIG. 8 are views for explaining coupling of the cover member and the sealing member of the UHF partial discharge detection sensor having a leak-tight structure according to one embodiment of the present disclosure, and FIG. 9 to FIG. 12 are views for explaining a prior art of the UHF partial discharge detection sensor having a leak-tight structure according to one embodiment of the present disclosure.

### Embodiment 1

Referring to FIG. 1, a UHF partial discharge detection sensor 100 having a leak-tight structure according to one embodiment of the present disclosure may include a flange portion 110, an electrode rod 120, a sensor unit 130, a sealing member 140, and a cover member 150.

More specifically, the flange portion 110 may have a through hole provided therein, the electrode rod 120 may be inserted through the through hole provided in the flange portion 110, the sensor unit 130 may be provided at the upper end of the electrode rod 120 to detect partial discharge ultra-high frequency, the sealing member 140 may be provided between the electrode rod 120 and the flange portion 110, and the cover member 150 may support the lower end of the sealing member 140.

For example, the flange portion 110 may be manufactured by forging aluminum.

As illustrated in FIG. 2, the flange portion 110 may be integrally formed to include a bottom portion 111 formed in a circular plate shape having a first diameter and a protrusion portion 112 formed in a columnar shape having a second diameter by protruding from the center of the bottom portion 111.

Meanwhile, as illustrated in FIG. 9, in the case of the partial discharge detection sensor disclosed in the related art, a flange 510 and a ceramic assembly 520 may be coupled through welding.

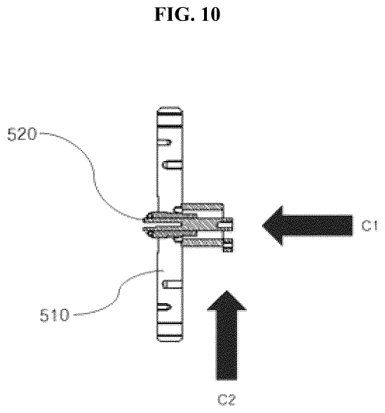

At this time, referring to FIGS. 10 to 12, when a horizontal impact C1 occurs in the sensor, the joint of a welded portion is separated, and when a vertical impact C2 is applied, the model of the electrode rod inserted into the flange 510 is deformed, causing the ceramic assembly 520 to be damaged, which is a disadvantage in that it is vulnerable to impact.

That is, since the flange portion 110 is formed as an integral piece of aluminum material, the conventional partial discharge detection sensor formed of stainless-steel material is heavy and has difficulties such as safety accidents in a one-person work environment or a high-altitude work environment.

In addition, in the past, in order to form the ceramic assembly and flange as an integral structure, the size of a spacer, electrode, electrode patch, or the like should be changed, and this causes a problem of performance degradation such as a decrease in sensor sensitivity.

In addition, in order to manufacture an integrated structure while using the conventional ceramic assembly as it is, a flange reflecting the adapter shape of the ceramic assembly should first be machined, and an electrolytic polishing process to smoothly process the metal surface after the flange is machined may be performed.

Thereafter, the ceramic assembly and the flange are coupled through welding processing, but the chemical agent used in the polishing process of the flange may react with the ceramic assembly and cause discoloration, or the like, so there is a problem that it is difficult to form an integrated structure while using the ceramic assembly as it is.

In contrast, the UHF partial discharge detection sensor 100 having a leak-tight structure of the present disclosure has a shape in which the flange 510 and the ceramic assembly 520 are integrally coupled, and thus, welding between the flange 510 and the ceramic assembly 520 is unnecessary, and leakage of insulating gas due to damage upon impact can be effectively prevented.

That is, in the case of the present disclosure, as illustrated in FIG. 3, since there is no coupled portion due to welding, or the like, the shape of the flange portion 110 can be stably maintained without cracks or damage even under horizontal impact C1 and vertical impact C2, thereby ensuring airtightness of the internal space.

In addition, since it is provided as an integral shape made of aluminum, the weight of the sensor can be reduced, problems such as discoloration due to chemical reaction with chemicals can be effectively prevented, and leakage of insulating gas can be effectively prevented without performance degradation such as sensor sensitivity degradation.

Meanwhile, the through hole is formed by penetrating the center of the bottom portion 111 and the protrusion portion 112, and the first diameter can be formed larger than the second diameter.

As another example, the diameter of the through hole may be determined corresponding to the shape of the electrode rod 120.

Meanwhile, referring to FIG. 4, the sealing member 140 includes a first O-ring 141 coupled to the surface of the bottom portion 111 of the flange portion 110 and a second O-ring 142 coupled to the inner peripheral surface of the protrusion portion 112 of the flange portion 110, thereby forming a double sealing structure and effectively preventing leakage of insulating gas.

To this end, the bottom portion 111 and the protrusion portion 112 may include a seating groove in which the first O-ring 141 and the second O-ring 142 are seated.

Therefore, the sealing member 140 is coupled to the flange portion 110, and the first O-ring 141 and the second O-ring 142 are seated inside the flange portion 110, so that the sealing member 140 can be stably mounted to the flange portion 110 even under horizontal impact C1 and vertical impact C2, and the sealing property can be further improved.

Meanwhile, referring to FIG. 5, the cover member 150 may have a seating groove 151 formed on one surface, and a seating member 152 may be inserted into the seating groove 151 to support the lower end of the sealing member 140.

Here, the height of the seating member 152 may be formed higher than the depth of the seating groove 151, and accordingly, the seating member 152 can prevent the sealing member 140 from being detached.

In this case, the sealing member 140 and the cover member 150 are provided with at least one hole penetrating the surface, and by fastening the bolt while matching the positions of the holes of the sealing member 140 and the cover member 150, the sealing member 140 and the cover member 150 can be more firmly coupled.

As another example, referring to FIGS. 6 to 8, the sealing member 140 may have a fastening protrusion 143 having a preset pattern formed on one side of the lower end surface in contact with the seating member 152, and the seating member 152 may have a fastening groove 153 formed on one side of the surface in contact with the lower end surface of the sealing member 140 corresponding to the fastening protrusion 143.

Accordingly, the fastening protrusion 143 of the sealing member 140 may be coupled to the fastening groove 153 of the seating member 152, thereby preventing the sealing member 140 from being detached even under impact, or the like.

In addition, a first filler may be applied to the joint surface of the seating member 152 and the sealing member 140 to fill the portion between the seating member 152 and the sealing member 140 with an air gap.

For example, the first filler may be provided in the form of a paste made of a metal material.

### Embodiment 2

For example, a partial discharge detection system using a UHF partial discharge detection sensor 100 having a leak-tight structure may include a sensing data collection unit, a leakage determination unit, a sensor error determination unit, and a wireless communication unit.

The sensing data collection unit may collect data collected from the UHF partial discharge detection sensor 100 having the leak-tight structure at preset intervals.

In addition, the sensor error determination unit may determine reliability of data collected from the sensing data collection unit, and when the reliability of the data exceeds a preset reference value, the data collected from the sensing data collection unit may be transmitted to the leakage determination unit.

For example, the reliability of the data can be calculated based on an average value and standard deviation of the data collected for a preset first unit time.

The leakage determination unit may determine whether there is a leakage of insulating gas using only the data whose reliability has been verified through the error determination unit, immediately transmit a call signal to a preset manager (user) terminal through the wireless communication unit when the leakage of the insulating gas is detected, and perform an emergency stop of the operation of the power equipment in which the UHF partial discharge detection sensor 100 having the leak-tight structure is installed.

More specifically, the sensing data collection unit is equipped with an identical sensor within a preset first radius from the measurement sensor, which is the UHF partial discharge detection sensor 100 having the leak-tight structure, as a comparison sensor, and the sensor error determination unit may calculate a sensor failure probability (S_{TR}) using data collected from the measurement sensor and the comparison sensor and a comparison target time.

In addition, the sensing error determination unit may extract the comparison target time, which is a time when a measurement value change rate of the data collected from the measurement sensor exceeds a preset first rate.

In this case, the first radius has a higher accuracy when compared as it gets closer to the measurement sensor, and is ideally located within a radius of 10 mm to 500 mm from the center position of the measurement sensor, and the first rate may be set to a rate of 25% to 30%, and the setting of the first rate may be changed from a minimum of 10% to a maximum of 90% depending on the type of the measurement sensor and the surrounding environment.

In addition, in a method for calculating the measurement value change rate of the sensing data, the measurement value change rate may be calculated by taking the absolute value by dividing the Tt1 measurement value by the value obtained by subtracting the Tt1 measurement value measured at time t1, which is a time interval of ta, from the Tt2 measurement value measured at time t2 within the time range of the sensing data collected from the sensing data collection unit, multiplying the result by 100, and then dividing the result by 100.

For example, when the time interval set through the manager terminal is 2 seconds, the total measurement time from the operation of the UHF partial discharge detection sensor which is the current measurement sensor to the end thereof is 2,000 seconds, the measurement value measured at 1,520 seconds is 25, and the measurement value measured at 1,518 seconds is 36.6; the measurement value change rate may be calculated as 46.4% (100*(25−36.6)/25). At this time, when the ratio set through the above manager terminal is 30%, since the measurement value change rate exceeds 30%, 1,518 seconds may be extracted as the comparison target time.

Meanwhile, the sensor error determination unit may extract the sensing data corresponding to n arbitrary times in the sensing data as the comparison target time when there is no time at which the measurement value change rate exceeds the preset ratio.

Here, the method of extracting n times from the sensing data may be extracted using a program to which a programming language is applied, and the programming language may mean python, Java, C language, C++, JavaScript, Go, Ruby, Swift, Kotlin, PHP, C# (C Sharp), or the like.

For example, the method of extracting n random times from the sensing data using python may be performed by setting a time range in which the sensor in the sensing data operates using the Random module and the Datetime module and then extracting n random times, or by using the Numpy module.

In addition, another method of extracting n times from the sensing data may be performed by applying the Fisher-Yates shuffle algorithm to the time range of the sensing data to randomly extract n times from the sensing data.

Meanwhile, in the n times extracted from the sensor error determination unit, n means a natural number that may vary depending on the operating environment set through the manager terminal, and the meaning of the arbitrary time may mean a time extracted in a random format without any regularity from the entire time collected from the sensing data.

Through the above process, the sensing data collection unit may transmit sensing data, which is a set of measurement values collected from at least two or more measurement sensors, to the manager terminal through the wireless communication unit. Moreover, the sensing data collection unit may divide a section in which the change rate of the sensing data does not exceed a preset change rate as a “standard state section” in response to a time interval set through the manager terminal, and divide a section in which the change rate exceeds the preset change rate as an “abnormal state section”.

Meanwhile, the sensor error determination unit can calculate a sensor failure probability (S_{TR}) according to the following [Mathematical Expression 1].

$${S}_{TR} = Min ( \frac{\vert {T}_{m s 1} - {T}_{cs 1} \vert + \vert {T}_{m s 2} - {T}_{cs 2} \vert + … + \vert {T}_{m s n} - {T}_{cs n} \vert}{n \times {T}_{msav}} ) \qquad [ Mathematical Expression 1 ]$$

(Here, S_{TR} is the sensor failure probability, Tₘₛ₁ is a measurement value of the measurement sensor at a first time, Tₘₛ₂ is a measurement value of the measurement sensor at a second time, Tₘₛ₃ is a measurement value of the measurement sensor at a third time, Tₘₛₙ is a measurement value of the measurement sensor at a nth time, Tₑₛₜ₁ is a measurement value of the comparison sensor at the first time, Tₑₛₜ₂ is a measurement value of the comparison sensor at the second time, Tₑₛ₃ is a measurement value of the comparison sensor at the third time, Tₑₛₙ is a measurement value of the comparison sensor at the nth time, Tₘₛₐᵥ is an average measurement value of the measurement sensor, and SE means an efficiency deviation of the measurement sensor.)

At this time, the efficiency deviation (SE) of the measurement sensor may be calculated according to [Mathematical Expression 2] below, and the average efficiency of the measurement sensor may be calculated according to [Mathematical Expression 3] below.

$$SE = {SE}_{av} - {SE}_{i} \qquad [ Mathematical Expression 2 ]$$

(Here, SEₐᵥ means the average efficiency of the measurement sensor, and SEᵢ means initial efficiency of the measurement sensor.)

$$S {E}_{av} = \frac{100}{n} ( \frac{{W}_{{OUT}_{1}}}{{W}_{{IN}_{1}}} + \frac{{W}_{{OUT}_{2}}}{{W}_{{IN}_{2}}} + … + \frac{{W}_{{OUT}_{n}}}{{W}_{{IN}_{n}}} ) \qquad [ Mathematical Expression 3 ]$$

(Here, W_{IN1} means power supplied to the measurement sensor at the first time, W_{OUT1} means power measured when the measurement value sensed by the measurement sensor at the first time is output as an electric signal, W_{IN2} means power supplied to the measurement sensor at the second time, W_{OUT2} means power measured when the measurement value sensed by the measurement sensor at the second time is output as an electric signal, W_{INn} means power supplied to the measurement sensor at the nth time, and W_{OUTn} means power measured when the measurement value sensed by the measurement sensor at the nth time is output as an electric signal.)

In this case, the n times mentioned in the above [Mathematical Expression 1] to [Mathematical Expression 3] may mean the number of multiple time points or randomly extracted time points at which the measurement value change rate of the sensing data extracted by the error determination unit exceeds a preset rate.

For example, in a state where a first partial discharge detection sensor provided as the measurement sensor and a second partial discharge detection sensor provided as a comparison sensor of the same model as the partial discharge detection sensor and within a radius of 10 mm are provided, the sensing data collection unit may measure an input/output voltage of the first partial discharge detection sensor and current consumption inside the measurement sensor.

In this case, when three times are extracted from the measurement sensor, the voltages supplied during the extracted first to third times are 4.9 V, 5 V, and 5 V, the measurement sensor consumes 1 mA, 0.9 mA, and 1.1 mA of current at the corresponding times, and the measurement sensor outputs 10 mV, 9 mV, and 11 mV, the input power (W_{IN1}) supplied to the measurement sensor at the first time may be calculated as 0.0049 W (4.9 V*0.001 A), the input power (W_{IN2}) at the second time may be calculated as 0.0045 W (5 V*0.0009 A), and the input power (W_{IN3}) at the third time may be calculated as 0.0055 W (5 V*0.0011 A). In addition, the output power (W_{OUT1}) of the first time output from the measurement sensor may be calculated as 0.00001 W (0.01 V*0.001 A), the output power (W_{OUT2}) of the second time may be calculated as 0.000081 W (0.009 V*0.0009 A), and the output power (W_{OUT3}) of the third time may be calculated as 0.0000121 W (0.011 V*0.0011 A).

In addition, the average efficiency (SEₐᵥ) of the above measurement sensor is 0.2 (100/3*(0.00001/0.0049+0.000081/0.0045+0.0000121/0.0055)) based on the above [Mathematical Expression 2], and when the initial efficiency (SEᵢ) provided by the manufacturer of the measurement sensor is 0.2%, the efficiency deviation (SE) of the measurement sensor may be calculated as 0 based on the [Mathematical Expression 3].

As the calculated value of the average efficiency (SEₐᵥ) of the measurement sensor becomes lower, the sensor may be determined to be more efficient; as the calculated value of the average efficiency (SEₐᵥ) of the measurement sensor becomes higher, the sensor may be determined to be more inefficient; and as the calculated value becomes higher than the initial efficiency, the probability of failure in the electrical domain of the sensor may be determined to be higher.

Meanwhile, when the initial efficiency (SEᵢ) of the measurement sensor is not provided, the efficiency measured under preset conditions through the sensing data collection unit may be set as the initial efficiency (SEᵢ).

In addition, sensing data according to the operation of the first partial discharge detection sensor may be collected from 0 seconds to 2,700 seconds. In this case, the average measurement value of the first partial discharge detection sensor (measurement sensor) may be 35, and the measurement values measured at three randomly extracted times through the program may be extracted as 29 (485 seconds), 35 (1893 seconds), and 41 (2021 seconds).

In addition, when the measurement values measured at the same time and each time from the second partial discharge detection sensor (comparison sensor) operating simultaneously with the first partial discharge detection sensor are 30.1 (485 seconds), 32.5 (1893 seconds), and 43 (2021 seconds), the failure probability (S_{TR}) of the first partial discharge detection sensor may be calculated as about 5.33% (Min((|29−30.1|+|35−32.5|+|41−43|)/(3*35)*100+0), 100) based on the [Mathematical Expression 1].

As another example, the sensor error determination unit may also calculate the sensor failure probability (S_{TR}) according to the following [Mathematical Expression 1-2] that reflects the weight according to the distance between the measurement sensor and the comparison sensor.

$${S}_{TR} = Min ( \frac{\vert {T}_{m s 1} - {T}_{cs 1} \vert + \vert {T}_{m s 2} - {T}_{cs 2} \vert + … + \vert {T}_{m s n} - {T}_{cs n} \vert}{n \times {T}_{msav}} \times {D}_{v} \times 100 + SE , 100 ) \qquad [ Mathematical Expression 1 - 2 ]$$

(Here, Dᵥ means distance weight of the measurement sensor and the comparison sensor.)

In this case, the distance weight (Dᵥ) of the measurement sensor and the comparison sensor is applied in response to the weight set through the user terminal, and the weight may be changed.

Therefore, according to the present disclosure as described above, the purpose thereof is to provide the UHF partial discharge detection sensor having a leak-tight structure that can effectively prevent the leakage of insulating gas by preventing damage or deformation of the welding portion and maintaining the internal airtightness when an impact occurs by including a flange portion in which a protrusion portion is formed.

In addition, according to one embodiment of the present disclosure, a control method of a partial discharge detection system using the UHF partial discharge detection sensor having a leak-tight structure can be recorded on a computer-readable medium including program commands for performing operations implemented by various computers. The computer-readable medium may include program commands, data files, data structures, or the like alone or in combination. In the media, the program commands may be specially designed and constructed for the present disclosure or may be known and available to those skilled in the computer software arts. Examples of computer-readable recording media include magnetic media such as hard disks, floppy disks, and magnetic tapes, optical media such as CD-ROMs and DVDs, magneto-optical media such as floptical disks, and hardware devices specifically configured to store and execute program commands such as ROMs, RAMs, and flash memories. Examples of program instructions include not only machine language codes such as those generated by a compiler, but also high-level language codes that can be executed by a computer using an interpreter, or the like.

Although the present disclosure has been described with limited embodiments and drawings, the present disclosure is not limited to the embodiments described above, and various modifications and variations can be made from these descriptions by those skilled in the art to which the present disclosure belongs. Therefore, the present disclosure should be understood only by the scope of the patent claims described below, and all equivalent or equivalent modifications thereof are considered to fall within the scope of the present disclosure.

1. A ultra-high frequency (UHF) partial discharge detection sensor having a leak-tight structure, the UHF partial discharge detection sensor comprising:
a flange portion having a through hole formed therein;
an electrode rod inserted through the through hole formed in the flange portion;
a sensor unit provided at an upper end of the electrode rod to detect partial discharge ultra-high frequency;
a sealing member provided between the electrode rod and the flange portion; and
a cover member supporting a lower end of the sealing member.

2. The UHF partial discharge detection sensor of claim 1, wherein the flange portion is integrally formed to include a bottom portion formed in a circular plate shape having a first diameter and a protrusion portion formed in a columnar shape having a second diameter by protruding from a center of the bottom portion,
the through hole is formed by penetrating the centers of the bottom portion and the protrusion portion, and
the first diameter is larger than the second diameter.

3. The UHF partial discharge detection sensor of claim 2, wherein the sealing member includes
a first O-ring coupled to a surface of the bottom portion of the flange portion, and
a second O-ring coupled to an inner circumference of the protrusion portion of the flange portion.

4. The UHF partial discharge detection sensor of claim 1, wherein a seating groove is formed on one surface of the cover member, and
a seating member is inserted into the seating groove to support the lower end of the sealing member.

5. The UHF partial discharge detection sensor of claim 4, wherein the seal member includes a fastening protrusion having a preset pattern formed on one side of a lower end surface in contact with the sealing member,
the seating member includes a fastening groove formed to correspond to the fastening protrusion on one side of a surface in contact with the lower end surface of the sealing member, and
a first filler is applied to a joint surface of the seating member and the sealing member to fill a portion between the fixing member and the sealing member with an air gap.
